(19) United States
(12) Patent Application Publication
(10) Pub. No.: US 2008/0099232 A1
(43) Pub. Date: May 1, 2008

(54) THREE-DIMENSIONAL PRINTED CIRCUIT BOARD FOR USE WITH ELECTRONIC CIRCUITRY

(75) Inventor: Romi O. Mayder, San Jose, CA (US)

Correspondence Address: SCHNECK & SCHNECK, P.O. BOX 2-E, SAN JOSE, CA, 95109-0005, US

(73) Assignee: SILICON TEST SYSTEMS, INC., San Jose, CA (US)

(21) Appl. No.: 11/690,903

(22) Filed: Mar. 26, 2007

Related U.S. Application Data
(60) Provisional application No. 60/862,934, filed on Oct. 25, 2006.

(51) Int. Cl. H05K 1/02

(52) U.S. Cl. 174/259

(57) ABSTRACT

A method for forming and using a resulting patterned discrete section to interconnect a plurality of printed circuit boards having electrical contact pads. The patterned discrete section is comprised of one or more dielectric sheets having an exposed first surface and an exposed second surface and a plurality of electrically conductive compliant features on each of the two exposed surfaces. The plurality of electrically conductive compliant features are configured to electrically couple to the electrical contact pads on the plurality of printed circuit boards, thereby providing a discrete means to provide electrical coupling between the patterned discrete section and the plurality of printed circuit boards.

### CROSS-REFERENCE TO RELATED APPLICATION

This application claims priority from U.S. Provisional Patent Application Ser. No. 60/862,934 entitled “Three-Dimensional Printed Circuit Board with Electronic Circuitry” filed Oct. 25, 2006 which is hereby incorporated by reference in its entirety.

### TECHNICAL FIELD

The present invention is related generally to fabrication of mounting structures (e.g., printed circuit or wiring boards) for electronic devices. More specifically, the present invention is related to a fabrication technique for producing high density three-dimensional printed circuit boards.

### BACKGROUND

In many applications where space is at a premium, a non-planar (i.e., three-dimensional) printed circuit board (PCB) is advantageous. Engineers typically design individual PCBs for three-dimensional applications by using plastic mating connectors to connect boards to one another. Typically, the mating connectors are soldered to the printed circuit boards. The PCBs must first be plated with material compatible with solder processes to ensure a proper solder connection with low electrical contact resistance.

The mating connectors also occupy a large volume of space and care must be taken to mechanically align each printed circuit board to the mating connector on another printed circuit board. Due to their construction and material from which they are formed, the mating connectors inherently have electrical performance limitations which affect, for instance, electrical bandwidth and electrical current carrying capabilities.

Further, PCB dimensional tolerances must be well controlled to ensure precise and accurate alignment between mating connectors. Additionally, PCB thicknesses, both intra-board and board-to-board, must be well controlled to ensure proper depth of insertion into each of the multiple mating connectors.

With reference to FIG. 1, a prior art three-dimensional printed circuit board arrangement 100 includes a plurality of printed circuit boards 101. Each of the plurality of PCBs 101 includes through-holes 103A and blind holes 103B for external connections to internal routing layers (not shown). Generally, each of the plurality of PCBs 101 will be comprised of multiple dielectric sheets. Each dielectric sheet is comprised of an organic material such as fibrglass-reinforced epoxy resin (e.g., FR-4), polytetrafluoroethylene (e.g., Teflon®, a trademark of E.I. du Pont de Nemours & Co., Wilmington, Del.), Driclad®(a trademark of Endicott Interconnect Technologies, Inc., Endicott, N.Y.), and similar materials known to one of skill in the art. Since the plurality of dielectric sheets are nonconductive they are typically “seeded” and plated with a copper conductive layer (not shown directly). Each of the plurality of PCBs 101 is then electrically and mechanically coupled to one another by a plurality of male connectors 105 and a plurality of female connectors 107. Either prior or subsequent to interconnecting the plurality of PCBs 101, various types of electronic devices 109 (e.g., surface mounted integrated circuits) may be mounted to select one of the plurality of PCBs 101.

As clearly indicated in FIG. 1, the size of the required interconnects 105, 107 occupies a significant volume. In many applications, such as mounting three-dimensional PCBs on probe heads in automated test equipment (ATE) systems, the volume required by interconnects minimizes available space for circuitry and thus reduces either the functionality and/or the ability of the ATE system to probe a large number of electronic devices for testing. ATE testing is used to test functionality of a large plurality of complex integrated circuits (ICs) such as memory circuits or hundreds of dice on a wafer prior to sawing and packaging. Since the area and volume of a probe card is generally fixed for a particular testing application or environment, any volume occupied by interconnects reduces the number of ICs that may be mounted and, hence, the number of devices that may be tested in parallel.

FIG. 2 shows a block diagram of an automated test system 200 of the prior art. The test system 200 includes a test system controller 201, a test head 205, and a test prober 207. The test system controller 201 is frequently a microprocessor-based computer and is electrically connected to the test head 205 by a communication cable 203. The test prober 207 includes a stage 209 on which a semiconductor wafer 211 may be mounted and a probe card 213 for testing devices under test (DUTs) on the semiconductor wafer 211. The stage 209 is movable to contact the wafer 211 with a plurality of test probes 215 on the probe card 213. The probe card 213 communicates with the test head 205 through a plurality of channel communications cables 217.

In operation, the test system controller 201 generates test data which are transmitted through the communication cable 203 to the test head 205. The test head in turn transmits the test data to the probe card 213 through the plurality of communications cables 217. The probe card then uses these data to probe DUTs (not shown explicitly) on the wafer 211 through the plurality of test probes 215. Test results are then provided from the DUTs on the wafer 211 back through the probe card 213 to the test head 205 for transmission back to the test system controller 201. Once testing is completed and known good dice are identified, the wafer 211 is diced.

Test data provided from the test system controller 201 are divided into individual test channels provided through the communications cable 203 and separated in the test head 205 so that each channel is carried to a separate one of the plurality of test probes 215. Channels from the test head 205 are linked by the channel communications cables 217 to the probe card 213. The probe card 213 then links each channel to a separate one of the plurality of test probes 215. The number of available channels is at least partially dictated by the number of ICs which may be mounted on PCBs affixed to the probe card 213 in the volume available.

In order to further reduce the cost of testing in ATE systems, more devices must be tested in parallel. As more devices are tested in parallel, more routing layers are needed to route electrical test signals to and from devices under test (DUTs). Consequently, the numbers of PCBs increases substantially.

Therefore, what is needed is a simple, economical, and robust means of producing three-dimensional PCBs which minimizes dimensional tolerances and eliminate voluminous prior art mechanical interconnects while still providing a means to stack PCBs in a three-dimensional configuration.

### SUMMARY OF THE INVENTION

In an exemplary embodiment, the invention is a three-dimensional printed circuit board comprised of one or more printed circuit board layers. The one or more printed circuit board layers each has a plurality of electrical contact pads on at least one face of the printed circuit board layers. One or more metallic layers is formed on at least one surface of each of the one or more printed circuit board layers. One or more patterned discrete sections has as exposed first surface and an exposed second surface. The one or more patterned discrete sections also has a plurality of compliant features on each of the two exposed surfaces. The plurality of compliant features is configured to electrically couple to select ones of the plurality of electrical contact pads and provide an exclusive means to provide electrical coupling between select ones of the one or more patterned discrete sections and select ones of the one or more printed circuit board layers.

In another exemplary embodiment, the invention is a patterned discrete section to interconnect a plurality of printed circuit boards having electrical contact pads. The patterned discrete section is comprised of one or more dielectric sheets having an exposed first surface and an exposed second surface and a plurality of electrically conductive compliant features on each of the two exposed surfaces. The plurality of electrically conductive compliant features are configured to electrically couple to the electrical contact pads on the plurality of printed circuit boards, thereby providing an exclusive means to provide electrical coupling between the patterned discrete section and the plurality of printed circuit boards.

In another exemplary embodiment, the invention is a method of producing a patterned discrete section. The method comprises drilling a plurality of holes in one or more dielectric sheets, forming an electrically conductive malleable layer over at least one face of the one or more dielectric sheets, patterning the electrically conductive malleable layer with a plurality of finger-like structures, and etching an opening around each of the plurality of finger-like structures. A bending fixture is inserted into each of the plurality of holes from a side opposite to that on which the electrically conductive malleable layer is applied. Each of the plurality of finger-like structures is bent outward from the face on which the electrically conductive malleable layer is formed.

In another exemplary embodiment, the invention is a method of producing a patterned discrete section. The method comprises forming a plurality of metallic layers over at least one face of one or more dielectric sheets while varying a gas pressure. The gas pressure is varied such that adjacently formed layers of the plurality of metallic layers have varying degrees of tensile strength. The plurality of metallic layers is patterned with a plurality of finger-like structures. An opening is etched around each of the plurality of finger-like structures using a selective etchant. Each of the plurality of finger-like structures is allowed to bend outward away from the at least one face to form compliant features.

### BRIEF DESCRIPTION OF THE DRAWINGS

FIG. 1 is a cross-sectional view of a three-dimensional printed circuit board of the prior art requiring mating mechanical interconnects.

FIG. 2 is a block diagram of an ATE system of the prior art.

FIG. 3 is a cross-sectional view of an exemplary beryllium copper plated and patterned discrete section of a three-dimensional printed circuit board in accord with an embodiment of the present invention.

FIG. 4 is an exemplary cross-sectional view of a PCB in accord with an embodiment of the present invention.

FIG. 5 is an exemplary cross-sectional view utilizing the plated and patterned discrete section of FIG. 3 to interconnect printed circuit boards in a three-dimensional configuration.

### DETAILED DESCRIPTION

Embodiments of the present invention solve problems associated with prior art methods and apparatus for producing three-dimensional PCBs. These problems include controlling printed circuit board thicknesses accurately and area-based dimensional tolerance required by mechanical mating connectors. Further, the mating connectors may be completely eliminated and replaced by placement-tolerant patterned discrete sections (described below). Thus, embodiment of the invention significantly reduce the need to control the dimensional tolerances of the printed circuit board. The three-dimensional PCBs may be used for a wide variety of electronic applications including load boards in package test, burn-in boards for burn-in test, and probe cards for wafer test. In particular applications requiring large thermal loads, the three-dimensional PCBs may be attached to a water bock for thermal cooling of electronic devices allowing the three-dimensional PCBs to be used over an operating temperature range of −40° C. to −150° C.

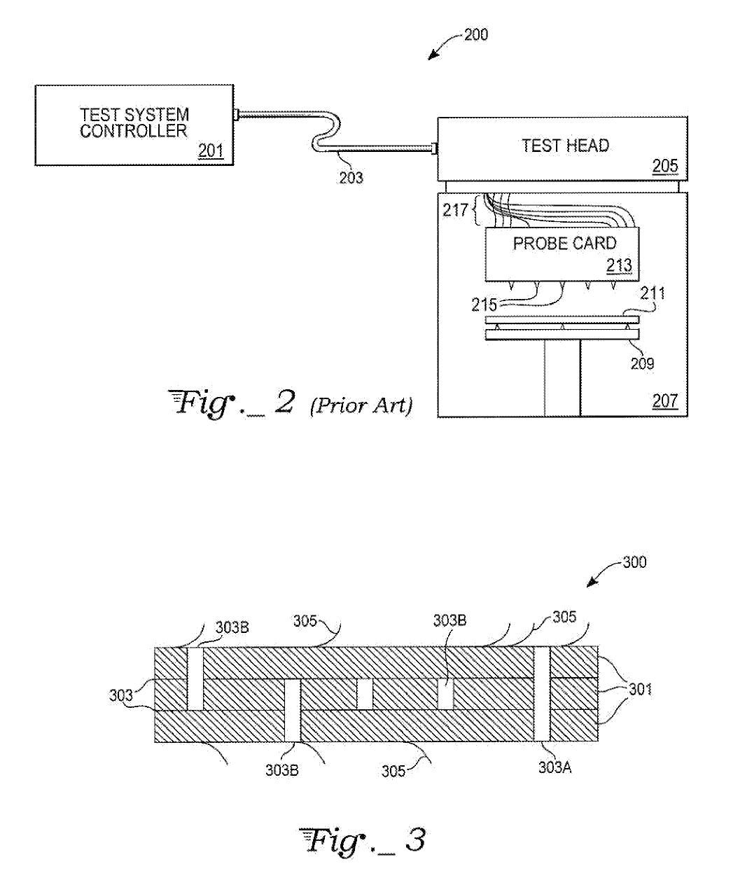

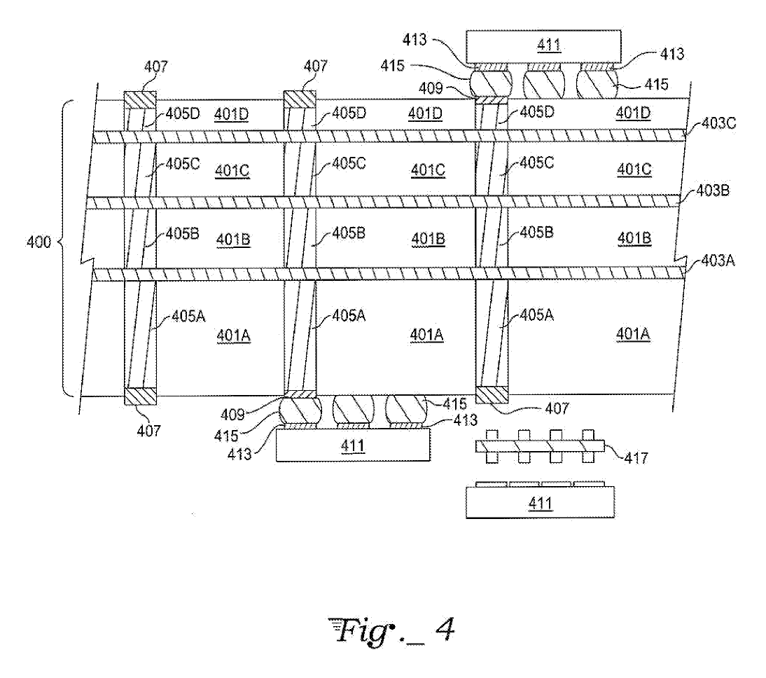

With reference to FIG. 3, an exemplary patterned discrete section 300 includes a plurality of dielectric sheets 301. Each of the plurality of dielectric sheets has a patterned metallic layer 303 plated and patterned on one or both sides prior to final assembly of the discrete section. The patterned metallic layer may be a deposited, plated, or sputtered copper or copper alloy.

Each of the plurality of dielectric sheets 301 may be comprised of, for example, any of the organic materials known in the art. Additionally, DiClad, CuClad and others (available from Arlon-MED, Rancho Cucamonga, Calif.). Park-Nelco 4000-13 (available from Park Electrochemical Corporation., Anaheim, Calif.), Rogers 3000/4000, Duroid® and others (available from Rogers Corporation, Rogers Conn.), Duraver® and others (available from Isola GmbH, Dueren, Germany) and other materials may all be employed. Each of the plurality of dielectric sheets 301 may be formed from other rigid, semi-rigid, and flexible electrically insulative materials as well. Additionally, each of the plurality of dielectric sheets 301 may be comprised of materials different from an adjacent layer.

Further, each of the plurality of dielectric sheets 301 may include a plurality of through-holes 303A and/or a plurality of blind holes 303B. The plurality of through-holes 303A and the plurality of blind holes 303B may each by plated or filled with an electrically conductive material. The patterned discrete section 300 also includes a plurality of metal fingers 305. The plurality of metal fingers 305 form electrical contacts between the patterned discrete section 300 and contact points or pads with other PCBs as described in more detail below.

In a specific exemplary mechanical for forming the plurality of metal fingers 305, a beryllium copper (BeCu) layer is patterned (e.g., by photolithographic means) with finger-like structures (not shown). The BeCu layer may be formed over a first surface of a laser-drilled FR-4 substrate. Alternatively, may electrically conductive and malleable material may be used in place of the BeCu layer. A bending fixture is then inserted from a backside of the FR-4 substrate and force is applied force to the backside of the patterned BeCu layer thus bending or partially folding the patterned fingers outward.

In another specific exemplary mechanical process for forming the plurality of metal fingers 305, compliant spring types known in the art may be employed. Each of the plurality of mechanical springs may take various forms known in the art and include various compressional spring types such as volute, helical, coil, cantilever, or leaf springs. Both macro-mechanical and micro-mechanical methods for producing various forms of spring elements are also known in the art.

In a specific exemplary chemical process for forming the plurality of metal fingers 305, a plurality of metal layers may be formed, for example by sputtering or otherwise chemically depositing (e.g., by chemical vapor deposition (CVD)) over a dielectric layer formed on an FR-4 substrate. During the metal forming process, argon pressure is varied so that adjacent metal layers have varying degrees of tensile strength. The BeCu layer is patterned (e.g., by photolithographic means) with finger-like structures and etched. A highly selective etchant (dielectric to metal) is used to etch the underlying dielectric material while the metal layers act as a mask for the dielectric. The process creates partially folded-away fingers in the BeCu layer. Another specific chemical process which may be employed to form the fingers is found in U.S. Pat. No. 7,126,220, granted Oct. 24, 2006, to Lahiri et al.

In another specific exemplary chemical/mechanical process, the plurality of dielectric sheets 301 may be variously sized and subsequently attached to one another. Some of the plurality of dielectric sheets 301 may be plated with 0.5 ounce copper and others plated with 2 ounces of beryllium copper. The beryllium copper layers may then be plated with nickel and finally gold. Outer layers of the patterned discrete section 300 may alternatively be plated with materials such as copper, beryllium copper, nickel, Immersion Gold, cobalt gold. Flash Gold, or organic coated copper. Using a mechanical and/or chemical process, the patterned beryllium copper is partially folded away from the core material to create a mechanically compliant membrane.

The patterned discrete section 300 (FIG. 3) may be used with a variety of different printed circuit board types. For example, in FIG. 4, an exemplary advanced printed circuit board 400 includes a plurality of dielectric sheets 401A-401D. Each of the plurality of dielectric sheets 401A-401D may be comprised of materials similar to that employed with reference to FIG. 3. Alternatively, each of the plurality of dielectric sheets 401A-401D may be comprised of materials dissimilar to one other and/or dissimilar to the plurality of dielectric sheets 301. Additionally, each of the plurality of dielectric sheets 401A-401D may be formed from rigid, semi-rigid, and flexible electrically insulative materials known in the art.

The advanced printed circuit board 400 is particularly suitable for application involving via holes produced in a large number of layers. One or more conductive plating layers 403A-403C is applied to one or both faces of the plurality of dielectric sheets 401A-401D. Note that, for example, the top conductive plating layer 403C may actually be comprised of two different layers, one on an uppermost surface of the third dielectric sheet 401C and another on the lower surface of the fourth dielectric sheet 401D. The one or more conductive plating layers 403A-403C may be continuous layers. Alternatively, the one or more conductive plating layers 403A-403C may be patterned layers forming electrical routing traces. Each of the plurality of dielectric sheets 401A-401D may be formed from materials of different thicknesses or equal thicknesses and each of the one or more conductive plating layers 403A-403C may be optimized in thickness for a given application. For example, a ground or power layer may require a thicker conductive plating than a high frequency, low current data signal. Also, the one or more conductive plating layers 403A-403C may be comprised of a different conductive material such as copper, nickel, tantalum, tungsten, titanium, gold and other conductive materials known in the art depending upon electrical and thermal needs for a particular layer.

Unlike fabrication techniques employed in the prior art, each of the plurality of dielectric sheets 401A-401D has a plurality of holes drilled (e.g., by mechanical or laser drilling techniques, known in the art) and substantially filled prior to lamination to form the advanced printed circuit board 400. If needed to provide electrical isolation, small anti-pads (not shown) may be added to one or more faces of a dielectric sheet. Once the plurality of via holes are drilled, they are either fully or substantially filled with a conductive material thus forming substantially filled conductive vias 405A-405D. A substantial fill will be sufficient to assure both thermal and electrical continuity between each end of the substantially filled conductive vias 405A-405D. The conductive material may include individual materials or combinations of materials such as copper, titanium, tungsten, tantalum and other conductive materials known in the art. Blind or buried vias (not shown) may also be fabricated using this technique by drilling only through one or more of the plurality of dielectric sheets 401A-401D prior to lamination.

In addition to being excellent electrical conductors, the substantially filled conductive vias 405A-405D are also excellent thermal conductors. The conductive vias 405A-405D constructed as described herein conduct heat better than prior art via holes which are made with silver epoxy or copper epoxy, even if the prior art holes could be fully filled. As an example, solid copper has a thermal conductivity of 400 W/m·K while silver epoxy has a thermal conductivity of 2 W/m·K and copper epoxy has a thermal conductivity of 1 W/m·K. Due to the high thermal conductivity of the conductive vias 405A-405D, the advanced printed circuit board 400 may mate to a thermal water block (not shown) to dissipate heat generated in and around the advanced printed circuit board 400. In such a case, the conductive vias 405A-405D act as low impedance thermal paths for heat to conduct from one side of the advanced printed circuit board 400 to the other. If the advanced printed circuit board 400 is air cooled, the conductive vias 405A-405D act as conductive/convective heat sinks removing heat from the advanced printed circuit board 400.

Assembly of the advanced printed circuit board 400 may be completed once each of the plurality of dielectric sheets 401A-401D has received the one or more conductive plating layers 403A-403C and the conductive vias 405A-405D are substantially filled. Each of the plurality of dielectric sheets 401A-401D are sequentially laminated. Sequential lamination allows through-holes to have aspect ratios of 50:1 or greater.

In a specific exemplary embodiment, the advanced printed circuit board 400 is fabricated from two types of dielectrics (not shown). One dielectric is referred to as a prepreg and the other dielectric is referred to as a core. The prepreg is comprised of the same material composition as the core but has not been fully cured (i.e., hardened). First, a layer of copper is deposited on both sides of the core material by, for example, sputtering. Secondly, the deposited copper is plated on both sides by use of a traditional photolithography process. Via holes are drilled (e.g., mechanically formed or by laser ablation) through the core followed by a subsequent plating/filling of the drilled via holes thus electrically connecting opposing layers of copper on the core. A layer of copper is deposited on one side of the prepreg material. The prepreg copper layer is then patterned and via holes are drilled.

In this specific exemplary embodiment, lamination of the prepreg to the core layer is accomplished by first aligning fiducial marks on each layer to an opposing layer (the materials are semi-translucent). The two layers are laminated together by an application of heat and pressure (e.g., approximately 300° C. at 170 kPa (about 25 psig)) wherein the prepreg starts to flow and acts as an epoxy. The patterned copper image of the core material sinks into the prepreg and bonds. The copper image on the core material displaces prepreg material which flows to the outer edges of the panel. Excess prepreg material may be cut off after the last lamination step. Vias of the prepreg side are then plated thus making electrical contact with underlying traces on the core layer. The procedure is repeated as many times as needed to build up a multi-layer printed circuit board.

Although only four individual layers are shown in FIG. 4, fabrication techniques described herein are readily applicable to printed circuit boards containing 80 or more layers. For example, a 0.4 mm pitch (in both x- and y-directions) having via holes with an aspect ratio of 75:1 in a completed 0.375″ thick PCB with 80 layers has been produced by methods provided herein. Also, by substantially filling each of the via holes, solder is prevented from being wicked into the hole during subsequent mounting of electronic components on surfaces of the completed PCB.

With continued reference to FIG. 4, in a specific exemplary embodiment, outer layers of the advanced printed circuit board 400 are plated with nickel (not shown) to cover any surface imperfections that may have been created by the sequential lamination process. Nickel plating processes are known in the art. Since the vias have been made flat on the outer layers by use of the nickel plating process, the vias will have a large flat surface area that may be mated to a water block as described above. The heat generated by the devices on the PCB can now be removed more efficiently owing to enhanced thermal conductivity achievable through the smoothed surface.

After plating with nickel, a two step gold plating process may be used. First, gold is deposited over all exposed ends of the conductive vias 405A, 405D of the advanced printed circuit board 400 to a thickness of, for example, about 125 nanometers (i.e., approximately 5 μin). The set of solderable contact points 409 are masked with photoresist to prevent any additional gold plating. Remaining exposed contact points receive additional plating for a total gold thickness of about 1.25 μm (approximately 50 μin) forming a set of thickly plated contact pints 407. Hence, depending on the application of the via hole, a particular thickness of gold is plated allowing each via hole metallization to be optimized independent of a neighboring via. Alternatively, the conductive vias 405A-405D may be directly soldered, with or without a dog bone trace, and with or without a solder pad.

For example, the set of solderable contact points 409 plated with 125 nanometers of gold may be used to mount a plurality of integrated circuit devices 411. A plurality of device pads 413 on the integrated circuit devices 411 provides electrical contact pints to which contact devices may be mounted. The contact devices may include solder balls/solder paste 415 or balls from a ball grid array (BGA) or contacts from other package types. A mechanical interface 417, such as an interposer or socket, may be used to mount the integrated circuit devices 411 to the advanced printed circuit board 400 through the set of thickly plated contact points 407.

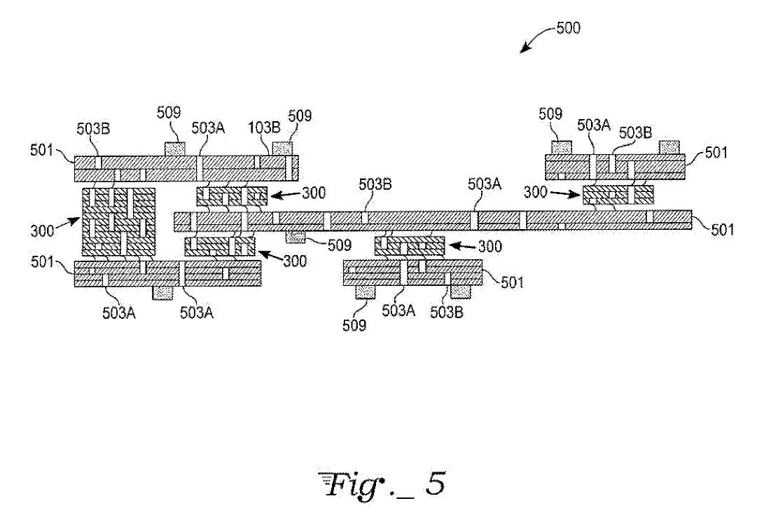

With reference to FIG. 5, an exemplary three-dimensional printed circuit board arrangement 500 includes a plurality of printed circuit boards 501. Each of the plurality of PCBs 501 include through-holes 503A and blind holes 503B for external connections to internal routing layers (not shown). Each of the plurality of PCBs 501 may be comprised of either discrete of multiple dielectric sheets. One of more of the plurality of PCBs 501 may be a high density PCB such as the advanced printed circuit board 400 (FIG. 4). Significantly, there is no requirement for mechanical male or female connectors as required in the prior are (see above). Each of the plurality of PCBs 501 is electrically interconnected by one or more of the patterned discrete sections 300 through electrical contact pads (not shown) on the face of one or more sides of the plurality of PCBs. 501. Various types of electronic devices 509 (e.g., surface mounted integrated circuits) may be mounted to one or more of the plurality of PCBs 501. The electronic devices 509 may be, for example, soldered or wire bonded to one or more of the plurality of PCBs 501.

The patterned discrete sections 300 drastically reduce the need for accurate and precise location and manufacturing of discrete sections of the exemplary three-dimensional printed circuit board arrangement 500. Further, ranges of thickness for each of the discrete sections can vary significantly since the plurality of metal fingers 305 (FIG. 3) automatically adjust for both intra-board and inter-board thickness variations.

Assembly of the various components can occur in a variety of ways known to one of skill in the art. For example, the patterned discrete sections 300 of the exemplary three-dimensional printed circuit board arrangement 500 may be soldered, laminated, or bonded to each other or to one or more of the plurality of PCBs 501, screwed together with nuts and bolts, riveted, epoxyed, or clamped together with metal plates.

In a specific exemplary embodiment, each discrete section of the exemplary three-dimensional printed circuit board arrangement 500 may be optimized electrically independently of other discrete sections. For example, each of the plurality of PCBs 501 (in addition to one or more of the patterned discrete sections 300) may be fabricated to have multiple controlled impedance values. By adjusting routing traces (not shown) and dielectric characteristics within each of the plurality of PCBs 501, impedance values of, for instance, 25 ohm, 50 ohm, and 75 ohm may be produced. Further, each of the plurality of PCBs and patterned discrete sections 300 may be optimized for manufacturability independently of other sections of the exemplary three-dimensional printed circuit board arrangement 500. Further, electrical crosstalk between signals may be minimized since more conductive layers are available for routing in less volume than was required under the prior art.

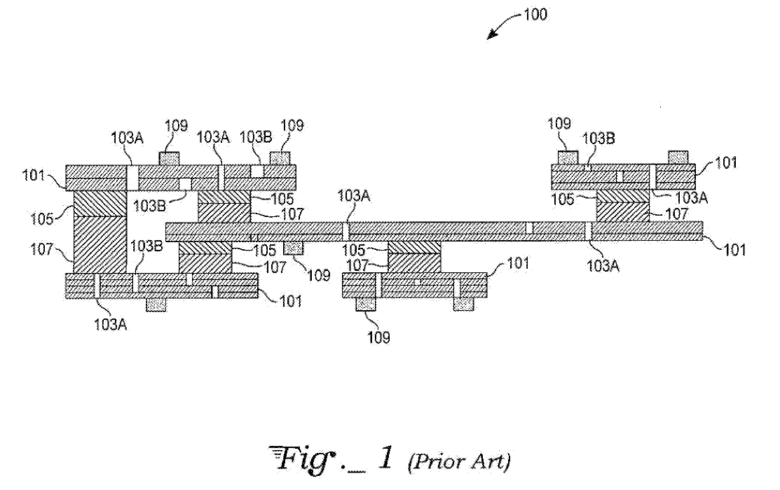

As disclosed herein, the exemplary three-dimensional printed circuit board arrangement 500 may be used in any application where a prior art printed circuit board is used including applications which previously used the prior art three-dimensional printed circuit board arrangement 100 (FIG. 1) that were electrically connected together by mating connectors. Additionally, since the mating connectors (typically formed from molded plastic) are no longer required, a range of temperatures (e.g., from −40° C. to +150° C.) under which the exemplary three-dimensional printed circuit board arrangement 500 may function has increased dramatically.

A skilled artisan will recognize that other parameters such as particular metallic alloys selected, core materials, specific layouts, and so on are exemplary only and may be varied depending upon circuitry requirements, volumes of available spaces, and other factors.

In the foregoing specification, the present invention has been described with reference to specific embodiments thereof. It will, however, be evident to a skilled artisan that various modifications and changes can be made thereto without departing from the broader spirit and scope of the present invention as set forth in the appended claims. For example, a skilled artisan will recognize that alternative techniques and methods may be utilized to plate or deposit certain layers described herein. The alternative techniques and methods are still included within a scope of the appended claims. For example, there are frequently several techniques used for forming a material in addition to plating (e.g., chemical vapor deposition, plasma-enhanced vapor deposition, epitaxy, atomic layer deposition, sputtering, etc.). Although not all techniques are amenable to all material types described herein, one skilled in the art will recognize that multiple methods for fabricating a material may be used. Also, various alloys, compounds, and multiple layers of stacked materials may be used, such as with conductive materials formed within the vias or between various layers of PCBs. These and various other embodiments and techniques are all within a scope of the present invention. The specification and drawings are, accordingly, to be regarded in an illustrative rather than a restrictive sense.

What is claimed is:

1. A three-dimensional printed circuit board comprising:
one or more printed circuit board layers, the one or more printed circuit board layers each having a plurality of electrical contact pads on at least one face of the printed circuit board layers;
one or more metallic layers formed on at least one surface of each of the one or more printed circuit board layers; and
one or more patterned discrete sections, the one or more patterned discrete sections having an exposed first surface and an exposed second surface, the one or more patterned discrete sections further having a plurality of compliant features on each of the two exposed surfaces, the plurality of compliant features configured to electrically couple to select ones of the plurality of electrical contact pads and thereby providing a discrete means to provide electrical coupling between select ones of the one or more patterned discrete sections and select ones of the one or more printed circuit board layers.

2. The three-dimensional printed circuit board of claim 1 wherein the plurality of compliant features are electrically conductive fingers fabricated through a chemical etching process, the fingers being formed from a material selected from the group consisting of beryllium copper and copper.

3. The three-dimensional printed circuit board of claim 1 wherein the plurality of compliant features are electrically conductive fingers fabricated through a mechanical forming process, the fingers being formed from a material selected from the group consisting of beryllium copper and copper.

4. The three-dimensional printed circuit board of claim 1 wherein the plurality of compliant features are electrically conductive fingers fabricated through a chemical etching and mechanical forming process, the fingers being formed from a material selected from the group consisting of beryllium copper and copper.

5. The three-dimensional printed circuit board of claim 1 wherein the plurality of compliant features are electrically conductive mechanical compressional springs.

6. The three-dimensional printed circuit board of claim 1 further comprising a plurality of electronic devices mounted to select ones of the one or more printed circuit board layers.

7. The three-dimensional printed circuit board of claim 1 wherein at least one of the one or more printed circuit board layers is an advanced printed circuit board, the advanced printed circuit board comprising a plurality of dielectric sheets, each of the plurality of dielectric sheets having a conductive film on at least one face thereof, the conductive film arranged to define electrical traces, each of the plurality of dielectric sheets further having a plurality of through-holes contained therein, the plurality of through-holes being substantially filled with an electrically conductive material with at least one of the plurality of through-holes arranged to traverse the advanced printed circuit board.

8. The three-dimensional printed circuit board of claim 7 wherein at least one of the plurality of through-holes has an aspect ratio of least 50:1.

9. The three-dimensional printed circuit board of claim 1 wherein each of the one or more printed circuit board layers has internal electrical routing layers.

10. A patterned discrete section to interconnect a plurality of printed circuit boards having electrical contact pads, the patterned discrete section comprising:
one or more dielectric sheets having an exposed first surface and an exposed second surface, the one or more dielectric sheets further having a plurality of electrically conductive compliant features on each of the two exposed surfaces, the plurality of electrically conductive compliant features configured to electrically couple to the electrical contact pads of the plurality of printed circuit boards, thereby providing a discrete means to provide electrical coupling between the patterned discrete section and the plurality of printed circuit boards.

11. The patterned discrete section of claim 10 wherein the plurality of electrically conductive fingers are fabricated through a chemical etching process, the plurality of electrically conductive fingers being formed from a material selected from the group consisting of beryllium copper and copper.

12. The patterned discrete section of claim 10 wherein the plurality of electrically conductive fingers are fabricated through a mechanical forming process, the plurality of electrically conductive fingers being formed from a material selected from the group consisting of beryllium copper and copper.

13. The patterned discrete section of claim 10 wherein the plurality of electrically conductive fingers are fabricated through a chemical etching and mechanical forming process, the plurality of electrically conductive fingers being formed from a material selected from the group consisting of beryllium copper and copper.

14. The patterned discrete section of claim 10 wherein the plurality of electrically conductive fingers are electrically conductive mechanical compressional springs.

15. The patterned discrete section of claim 10 wherein at least one of the one or more dielectric sheets has a through-hole to electrically couple the exposed surface and the exposed second surface.

16. A method of producing a patterned discrete section, the method comprising:
drilling a plurality of holes in one or more dielectric sheets;
forming an electrically conductive malleable layer over at least one face of the one or more dielectric sheets;
patterning the electrically conductive malleable layer with a plurality of finger-like structures;
etching an opening around each of the plurality of finger-like structures;
inserting a bending fixture into each of the plurality of holes from a side opposite to that on which the electrically conductive malleable layer is applied; and
bending each of the plurality of finger-like structures outward from the face on which the electrically conductive malleable layer is formed.

17. The method of claim 16 wherein the electrically conductive malleable layer is comprised of beryllium copper.

18. The method of claim 16 wherein the electrically conductive malleable layer is comprised of copper.

19. A method of producing a patterned discrete section, the method comprising:
forming a plurality of metallic layers over at least one face of one or more dielectric sheets while varying a gas pressure, the gas pressure being varied such that adjacently formed layers of the plurality of metallic layers have varying degrees of tensile strength;
patterning the plurality of metallic layers with a plurality of finger-like structures;
etching an opening around each of the plurality of finger-like structures using a selective etchant; and
allowing each of the plurality of finger-like structures to bend outward away from the at least one face to form compliant features.

20. The method of claim 19 wherein at least one of the plurality of metallic layers is comprised of beryllium copper.
